(19) United States
(12) Patent Application Publication
(10) Pub. No.: US 2023/0178345 A1
(43) Pub. Date: Jun. 8, 2023

(54) METHOD OF CLEANING CHAMBER

(71) Applicants: Kyoungran Kim, Suwon-si (KR); Hungsuk You, Seongnam-si (KR); Joongha Lee, Suwon-si (KR); Seokho Kim, Hwaseong-si (KR); Hoechul Kim, Yongin-si (KR); Kwangjin Moon, Hwaseong-si (KR); Sohye Cho, Hwaseong-si (KR)

(72) Inventors: Kyoungran Kim, Suwon-si (KR); Hungsuk You, Seongnam-si (KR); Joongha Lee, Suwon-si (KR); Seokho Kim, Hwaseong-si (KR); Hoechul Kim, Yongin-si (KR); Kwangjin Moon, Hwaseong-si (KR); Sohye Cho, Hwaseong-si (KR)

(21) Appl. No.: 18/062,543

(22) Filed: Dec. 6, 2022

(30) Foreign Application Priority Data
Dec. 7, 2021 (KR) 10-2021-0173869

(51) Int. Cl. H01J 37/32; H01L 23/00; G01N 23/223; G01N 21/62

(52) U.S. Cl. CPC H01J 37/32862; H01J 37/32091; H01L 24/80; H01L 24/05; G01N 23/223; G01N 21/62; H01J 2237/0225; H01L 2224/80009; H01L 2224/80895; H01L 24/94; H01L 2224/94; H01L 2224/05647; H01L 2224/05571; H01L 24/08; H01L 2224/08145; H10B 80/00

(57) ABSTRACT

A chamber cleaning method includes processing a wafer for a Cu-to-Cu bonding process using plasma in a chamber; and removing copper from the chamber. Removing copper includes forming copper oxide on an inner wall of the chamber by oxidizing copper in the chamber by a plasma treatment that uses a first gas, performing a first monitoring operation that monitors a copper contamination state in the chamber using an optical diagnostic method, removing the copper oxide by a plasma treatment that uses a second gas; and performing a second monitoring operation that monitors a copper contamination state in the chamber using the optical diagnostic method.

### CROSS-REFERENCE TO RELATED APPLICATION(S)

This application claims priority from Korean Patent Application No. 10-2021-0173869, filed on Dec. 7, 2021 in the Korean Intellectual Property Office, the contents of which are herein incorporated by reference in their entirety.

### TECHNICAL FIELD

Embodiments of the present inventive concept are directed to a chamber cleaning method, and to a chamber cleaning method of a substrate processing device.

### DISCUSSION OF RELATED ART

To improve integration and productivity, semiconductor products are produced using a die-to-wafer bonding method in which semiconductor chips are stacked three-dimensionally. Recently, methods for increasing the integration of semiconductor products using a wafer-to-wafer bonding method have been studied. In a wafer-wafer bonding method, a copper-to-copper bonding (C2C bonding) technique is being researched.

### SUMMARY

An embodiment of the present inventive concept provides a chamber cleaning method that is easy to perform and can efficiently manage contamination.

According to an aspect of the present inventive concept, a chamber cleaning method includes processing a wafer using plasma in a chamber; and removing copper from the chamber. Removing copper includes forming copper oxide on an inner wall of the chamber by oxidizing copper in the chamber by a plasma treatment that uses a first gas; performing a first monitoring operation that monitor is a copper contamination state in the chamber using an optical diagnostic method; removing copper oxide by a plasma treatment that uses a second gas; and performing a second monitoring operation that monitors the copper contamination state in the chamber using the optical diagnostic method.

According to an embodiment of the present inventive concept, a chamber cleaning method includes processing a wafer using plasma in a chamber; forming copper oxide on an inner wall of the chamber by oxidizing copper in the chamber by a plasma treatment that uses a first gas; removing the copper oxide by a plasma treatment that uses a second gas; and monitoring a copper contamination state in the chamber using optical emission spectroscopy (OES).

According to an embodiment of the present inventive concept, a chamber cleaning method includes monitoring a copper contamination state in a chamber; and removing copper from the chamber. Monitoring the copper contamination state includes analyzing a wavelength intensity representative of copper in the chamber with an optical diagnostic method; and deriving a correlation between a wavelength intensity value and a copper mass analyzed by a quantitative analysis method.

### BRIEF DESCRIPTION OF DRAWINGS

FIGS. 1A and 1B are flowcharts of a chamber cleaning method according to embodiments.

FIGS. 2A and 2B are, respectively, a flowchart and a schematic diagram of a copper-to-copper bonding process, according to embodiments.

FIGS. 3A and 3B are schematic cross-sectional views of semiconductor devices produced by a copper-to-copper bonding process according to embodiments.

FIG. 4 is a schematic cross-sectional view of a substrate processing apparatus according to embodiments.

FIGS. 5A to 5D illustrate a chamber cleaning method according to embodiments.

FIGS. 6A and 6B are graphs of spectroscopic intensity as functions of wavelength and number of cleanings, respectively, according to embodiments.

FIG. 7 is a graph of spectroscopic intensity as a function of number of cleanings according to embodiments.

FIG. 8 is a graph of copper contamination as a function of the number of cleanings according to embodiments.

FIG. 9 is a graph of spectroscopic intensity as functions of measurement example according to embodiments.

### DETAILED DESCRIPTION

Hereinafter, embodiments of the present disclosure will be described in detail with reference to the attached drawings.

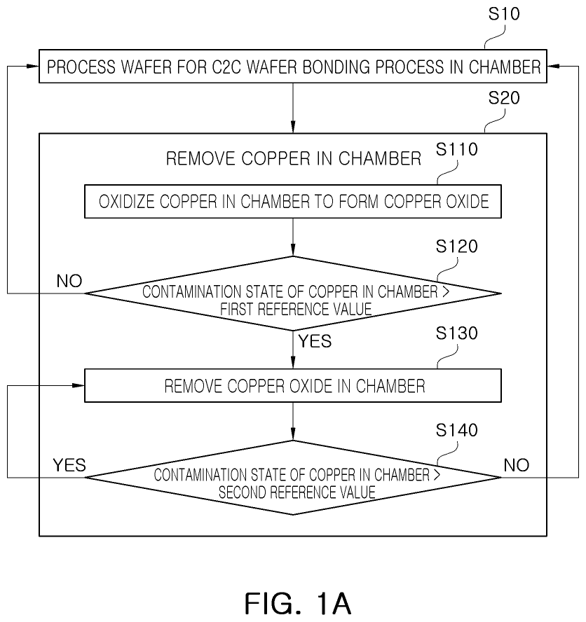

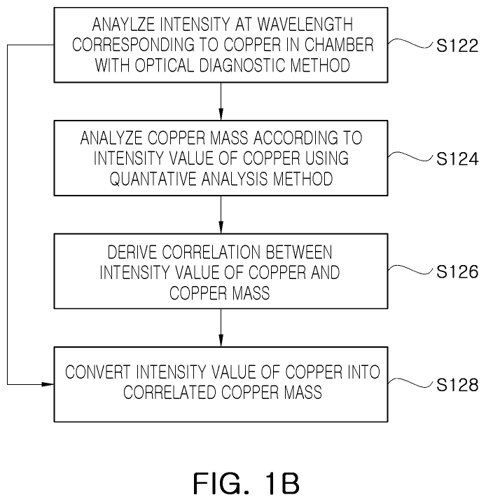

FIGS. 1A and 1B are flowcharts of a chamber cleaning method according to embodiments.

Referring to FIG. 1A, in an embodiment, a method of cleaning a chamber includes an operation S10 of processing a wafer for a copper-to-copper (C2C) bonding process in the chamber, and an operation S20 of removing copper from the chamber.

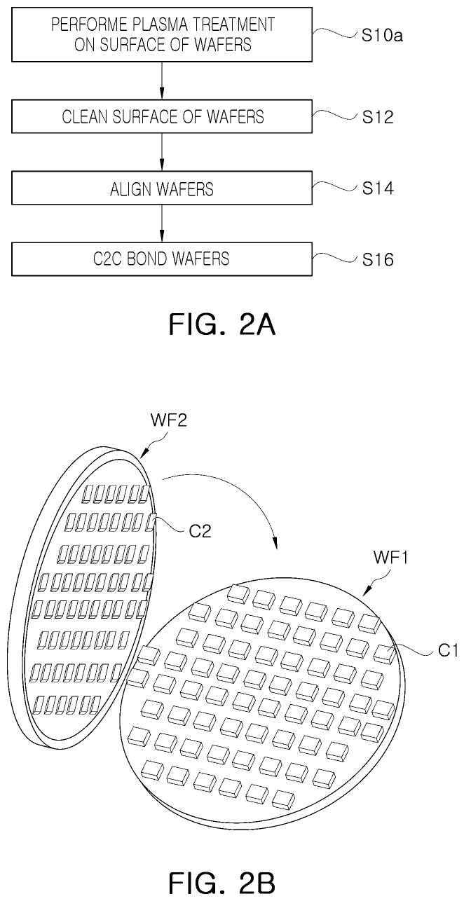

The operation S10 of processing a wafer for the copper-to-copper bonding process is a part of a set of copper-to-copper bonding process operations, such as an operation of activating a surface of the wafer using plasma. An overall copper-to-copper bonding process will be described in more detail below with reference to FIGS. 2A and 2B. In operation S10, for example, the surface of the wafer is processed using oxygen (O₂) and/or nitrogen (N₂) plasma.

The operation S20 of removing copper from the chamber includes removing copper from the contaminants generated while performing operation S10 of processing the wafer. When contamination by copper particles occurs in the chamber, the copper particles contaminate a wafer to be subsequently processed and may cause defects. Therefore, copper mass is monitored as a contaminant in the chamber and removed from the chamber at a certain point in time.

The operation S20 of removing copper from the chamber includes monitoring the copper contamination state in the chamber and removing copper from the chamber. In the operation of removing copper from the chamber, for example, copper is removed by a physical and/or a chemical method.

In embodiments, as illustrated in FIG. 1A, the operation S20 of removing copper from the chamber includes an operation S110 of oxidizing the copper in the chamber to form copper oxide, a first monitoring operation S120 of monitoring a copper contamination state in the chamber, an operation of removing copper oxide from the chamber S130, and second monitoring operation S140 of monitoring a copper contamination state in the chamber.

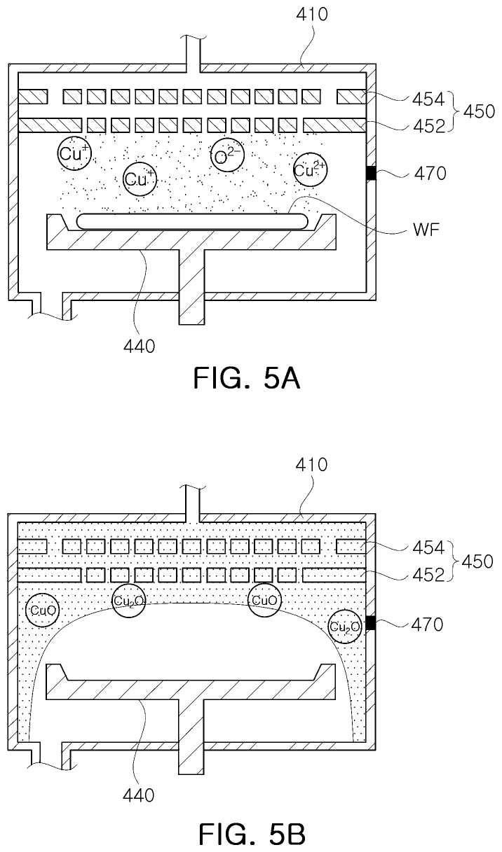

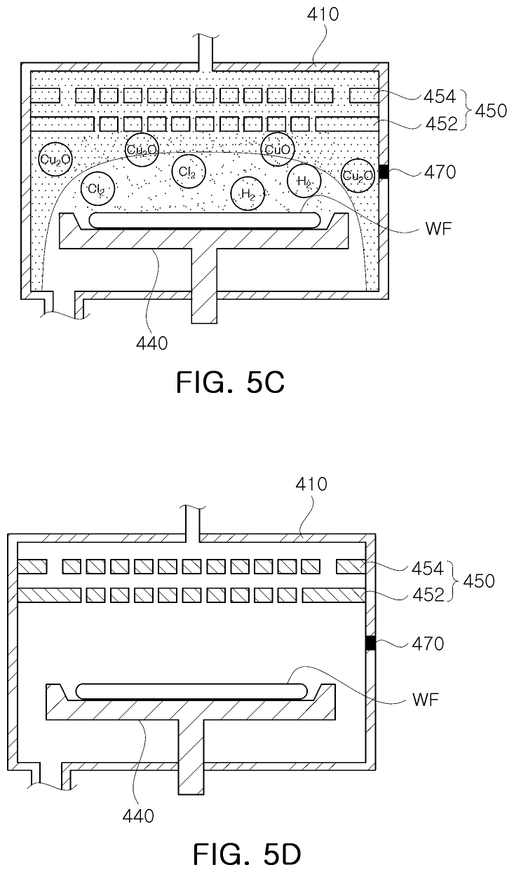

The operation S110 of oxidizing copper in the chamber to form copper oxide includes oxidizing copper in the chamber by a plasma treatment that uses a first gas to form copper oxide on an inner wall of the chamber. The first gas is, for example, oxygen (O₂). This will be described in more detail below with reference to FIGS. 5A and 5B.

In the first monitoring operation S120 of monitoring a copper contamination state in the chamber, the copper contamination stater in the chamber is monitored using an optical diagnostic method. The first monitoring operation S120 may be performed after the copper oxide forming operation S110 is performed, or may be continuously or intermittently performed in real time while the copper oxide forming operation S110 is being performed. The optical diagnostic method includes an analysis method that uses optical emission spectroscopy (OES).

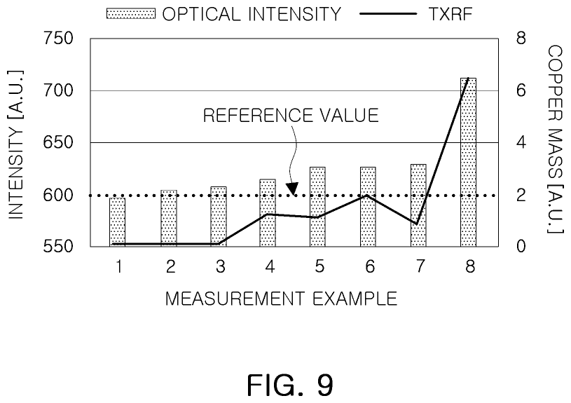

The first monitoring operation S120 includes determining whether a contamination state or a degree of contamination of copper in the chamber is greater than a first reference value. When the copper contamination state is less than or equal to the first reference value, the operation S10 of processing the wafer in the chamber is performed again. When the copper contamination state is greater than the first reference value, the operation S130 of removing copper oxide from the chamber is performed. A method of determining the first reference value will be described in more detail below with reference to FIG. 9.

The operation S130 of removing copper oxide from the chamber includes removing, by plasma treatment using a second gas, copper oxide formed in the operation S110 of forming the copper oxide S110. The second gas includes, for example, at least one of chlorine (Cl₂), hydrogen (H₂), or nitrogen (N₂). This will be described in more detail below with reference to FIG. 8C.

In the second monitoring operation S140 of monitoring a copper contamination state in the chamber, the copper contamination status in the chamber is monitored using an optical diagnostic method, similar to the first monitoring operation S120. The second monitoring operation S140 may be performed after the copper oxide removing operation S130 is performed, or may be continuously or intermittently performed in real time while the copper oxide removing operation S130 is being performed.

The second monitoring operation S140 includes determining whether the copper contamination state in the chamber is greater than a second reference value. When the copper contamination state is less than or equal to the second reference value, the operation S10 of processing the wafer in the chamber S10 is performed again. When the copper contamination state is greater than the second reference value, the operation S130 of removing copper oxide in the chamber S130 is performed again. In some embodiments, when the copper contamination state is greater than the second reference value, the operations described above, starting with the operation S110 of forming the copper oxide, are performed again. The second reference value may be equal to or less than the first reference value.

FIG. 1B is a flowchart of an embodiment of a method for monitoring copper contamination in a first monitoring operation S120 and a second monitoring operation S140. Each of the first monitoring operation S120 and the second monitoring operation S140 include an operation S122 of analyzing intensity of an optical signal at a wavelength corresponding to copper in the chamber by an optical diagnostic method, an operation S124 of analyzing copper mass according to the intensity value of the optical signal of copper by a quantitative analysis method, an operation S126 of deriving a correlation between the copper mass and the intensity value of the optical signal of copper, and an operation S128 of converting the intensity value of the optical signal into a correlated copper mass.

The operation S122 of analyzing the intensity of an optical signal at a wavelength corresponding to copper in the chamber by an optical diagnostic method uses, for example, an OES method. In an OES method, electrons of an element in plasma emit light while decaying from an excited state to a ground state, and the emitted light has a unique wavelength or wavelength range that depends on the element. An optical signal in the chamber is collected by the OES method, and the intensity of the optical signal at a wavelength that represents copper is analyzed.

The operation S124 of analyzing the copper mass according to the intensity value of the optical signal of copper by a quantitative analysis method includes, for example, performing quantitative analysis on samples that have different optical signal intensity values, to analyze an absolute amount of copper in each case. The quantitative analysis method includes, for example, a total reflection X-ray fluorescence (TXRF) analysis method. In some embodiments, a relationship between an intensity value of the optical signal of copper and an amount of copper is determined by analyzing the cross-section thereof by a transmission electron microscope (TEM) analysis method.

The operation S126 of deriving a correlation between an intensity value of the optical signal of copper and copper mass includes deriving a correlation between the intensity value of the optical signal and the copper mass, based on the copper mass analyzed in the operation S124.

The operation S128 of converting an intensity value of the optical signal into a correlated copper mass includes estimating the copper mass from the intensity value obtained in the operation S122 of analyzing intensity of an optical signal, based on a correlation derived in the operation S126. After the operations S124 and S126 are performed at least once, operation S128 is performed directly after the operation S122 of analyzing the intensity of the optical signal S122.

Thereby, to the copper mass can be estimates or analyzed in real time. Accordingly, when the operation S122 of analyzing the intensity of the optical signal is performed in real time from the chamber in an in-situ manner, the copper mass is also analyzed in real time.

In embodiments, each of the first monitoring operation S120 and the second monitoring operation S140 further includes an operation of determining a reference value of the optical intensity based on the correlated copper mass determined by operation S128. The reference value corresponds to at least one of the first or second reference values of FIG. 1A. Once the reference value is set, each of the first monitoring operation S120 and the second monitoring operation S140 includes an operation S122 of analyzing intensity of an optical signal and an operation of determining whether an intensity value of the optical signal of is greater than a reference value.

Hereinafter, each step of the chamber cleaning method according to embodiments will be described in more detail.

FIGS. 2A and 2B are, respectively, a flowchart and a schematic diagram of a copper-to-copper bonding process, according to embodiments.

Referring to FIGS. 2A and 2B, in an embodiment, the copper-to-copper bonding process includes an operation S10a of plasma treating surfaces of wafers WF1 and WF2, an operation S12 of cleaning the surfaces of the wafers WF1 and WF2, an operation S14 of aligning the wafers WF1 and WF2 with each other, and an operation S16 of copper-to-copper bonding the wafers WF1 and WF2. The wafers WF1 and WF2 to be bonded to each other include semiconductor structures C1 and C2, respectively, as illustrated in FIG. 2B. The semiconductor structures C1 and C2 are bonded to each other through copper-to-copper bonding.

An operation S10a of plasma treating surfaces of the wafers WF1 and WF2 corresponds to the operation S10 of processing the wafers described above with reference to FIG. 1A. For example, the surfaces of the wafers WF1 and WF2 are processed using oxygen (O₂) and/or nitrogen (N₂) plasma. For example, the surfaces of the wafers WF1 and WF2 are activated by radicals generated by plasma. For example, a dangling bond is formed on the surfaces of the wafers WF1 and WF2, but embodiments are not necessarily limited thereto.

The operation S12 of cleaning the surfaces of the wafers WF1 and WF2 includes rinsing the surfaces of the activated wafers WF1 and WF2. For example, by rinsing with deionized water, OH groups are formed on the surfaces.

The operation S14 of aligning the wafers WF1 and WF2 with each other includes aligning bonding surfaces of the two wafers WF1 and WF2 to face each other.

The operation S16 of copper-to-copper bonding the wafers WF1 and WF2 includes bonding by pressing and/or heating the aligned wafers WF1 and WF2 to each other. For example, OH groups of each of the wafers WF1 and WF2 are bonded while bonding the wafers WF1 and WF2 to each other.

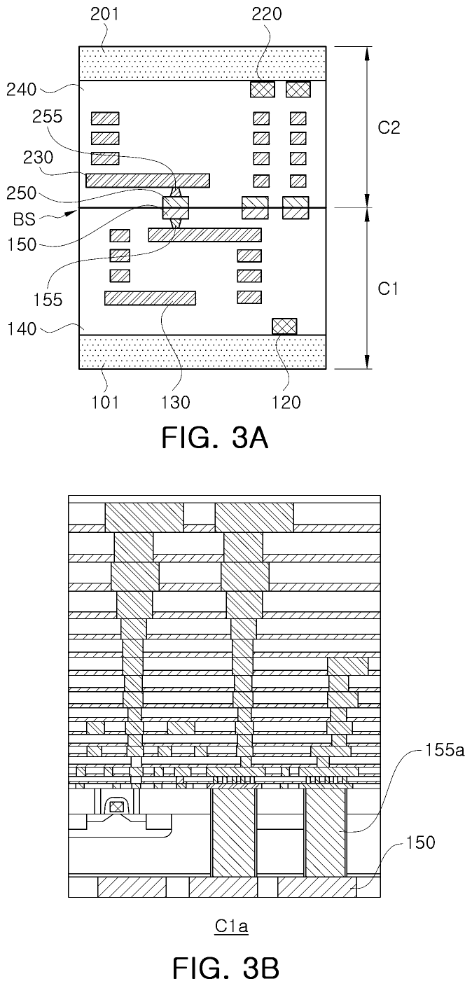

FIGS. 3A and 3B are schematic cross-sectional views of semiconductor devices produced by a copper-to-copper bonding process according to embodiments.

In an embodiment, FIG. 3A shows an example cross-section of a bonding structure of first and second semiconductor structures C1 and C2 bonded by a process described above with reference to FIGS. 2A and 2B. The first semiconductor structure C1 may include a first substrate 101, a first semiconductor device 120 disposed on the first substrate 101, a first insulating layer 140 disposed on the first substrate 101, first interconnection layers 130 disposed in the first insulating layer 140, first copper pads 150 exposed through a bonding surface BS, and first vias 155 that connect the first copper pads 150 and the first interconnection layers 130. Similarly, the second semiconductor structure C2 includes a second substrate 201, a second semiconductor device 220 disposed on the first substrate 201, a second insulating layer 240 disposed on the second substrate 201, second interconnection layers 230 disposed in the second insulating layer 240, second copper pads 250 exposed through a bonding surface BS, and second vias 255 that connect the second copper pads 250 and the first interconnection layers 230. The second semiconductor structure C2 is inverted and bonded to the first semiconductor structure C1. However, in embodiments, specific structures of the first and second semiconductor structures C1 and C2 are not necessarily limited to those illustrated in FIG. 3A.

In some embodiments, the first semiconductor structure C1 includes peripheral circuit elements of a NAND flash memory device or a DRAM device, and the second semiconductor structure C2 includes memory cells of the NAND flash memory device or the DRAM device. In some embodiments, the first semiconductor structure C1 includes pixels of an image sensor, and the second semiconductor structure C2 includes circuit elements that drive the pixels of the image sensor.

The first and second semiconductor structures C1 and C2 are bonded by bonding the first copper pads 150 and the second copper pads 250 and bonding an uppermost region of the first insulating layer 140 and a lowermost region of the second insulating layer 240 that surround the first and second copper pads 150 and 250. The bonding between the first copper pads 150 and the second copper pads 250 is the above-described copper (Cu)-to-copper (Cu) bonding, and the bonding between the first insulating layer 140 and the second insulating layer 240 is, for example, dielectric-to-dielectric bonding, such as SiCN—SiCN bonding. The first and second semiconductor structures C1 and C2 are bonded by hybrid bonding that includes copper (Cu)-to-copper (Cu) bonding and dielectric-to-dielectric bonding.

Referring to FIG. 3B, in a first semiconductor structure C1a according to embodiments, first vias 155a connected to the first copper pads 150 have a via-middle structure.

In a present embodiment, the first vias 155a have a through silicon via (TSV) shape. The first vias 155a are formed after performing a Front End Of Line (FEOL) that forms the first semiconductor device 120. In the first semiconductor structure C1a, compared to a via-last structure in which the first vias 155a are formed after both the FEOL and Back End Of Line (BEOL) processes are completed, a degree of integration of the semiconductor structure can be relatively increased. In addition, the first vias 155a have a smaller cross-sectional area and a higher density compared to a via-last structure. Accordingly, the first copper pads 150 also have a relatively small diameter, for example, in a range of from about 0.5 μm to about 5 μm, and have a small pitch, for example, in a range of from about 0.3 μm to about 2.5 μm. Accordingly, the area of the first copper pads 150 exposed through a bonding surface that corresponds to the lower surface of FIG. 3B increases, for example, in a range of from about 5% to about 50% of an entire bonding surface, or, for example, in a range of from about 30% to about 40%.

As described above, when a wafer bonding process is performed with wafers that include the highly integrated first semiconductor structure C1a, since areas of the first copper pads 150 exposed through an upper surface, which is a bonding surface, are relatively large, an amount of copper exposed in equipment such as a chamber, etc., while the copper-to-copper bonding process is being performed, may increase. Accordingly, copper contamination in the chamber should be monitored.

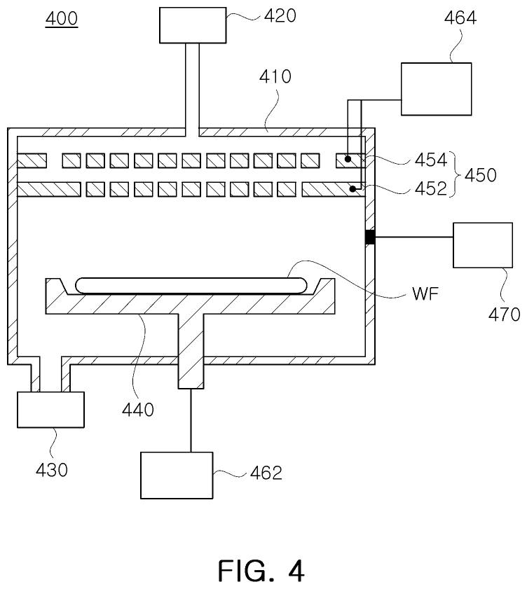

FIG. 4 is a schematic cross-sectional view of a substrate processing apparatus according to embodiments.

Referring to FIG. 4, in an embodiment, a substrate processing apparatus 400 may include a chamber 410, a gas supply unit 420, an exhaust unit 430, a substrate support unit 440, a shower head 450, and first and second power supply units 462 and 464, and an optical emission spectrometer 470. The substrate processing apparatus 400 performs the plasma treatment operation S10a described with reference to FIG. 2A on the wafer WF on the substrate support unit 440. In some embodiments, the substrate processing apparatus 400 may be a deposition apparatus or a dry cleaning apparatus. In a present embodiment, the substrate processing apparatus 400 uses a capacitively coupled plasma (CCP) method, but a plasma forming method of the substrate processing apparatus 400 is not necessarily limited thereto.

The chamber 410 provides a space in which plasma is formed and a space in which a surface treatment process is performed. The chamber 110 provides a sealed internal space in which the wafer WF is processed. A separate passage through which the wafer WF is carried in and out is provided on one side of the chamber 410. The chamber 410 is made of a metal, and includes, for example, at least one of aluminum (Al) or an alloy thereof.

The gas supply unit 420 supplies a process gas for plasma generation, and the process gas is supplied to a plasma generation region in the shower head 450 or on the shower head 450. The exhaust unit 430 includes an exhaust device that discharges residual gas and by-products from the chamber 410. For example, the exhaust device includes a vacuum pump.

The substrate support unit 440 is located in a lower part of the chamber 410, and supports the wafer WF while the wafer WF is being processed. The substrate support unit 440 includes, for example, at least one of an electrostatic chuck, a heater, or a susceptor. For example, the substrate support unit 140 supports the wafer WF by vacuum adsorption by an electrostatic chuck. In some embodiments, the substrate support unit 440 can be raised and lowered. The wafer WF on which the surface is processed is one of the wafers WF1 and WF2 on which the copper-to-copper bonding process described above with reference to FIGS. 2A and 2B is performed, and includes copper pads 150 and 250 (see FIG. 3A) that are exposed through the upper surface.

The shower head 450 is disposed above the substrate support unit 440, and the plasma generated inside the shower head 450 or above the shower head 450 is distributed and supplied onto the substrate support unit 440. The shower head 450 includes, for example, circular plate-shaped distribution plates and a plurality of through holes formed in each of the distribution plates.

The through holes can pass a substrate processing material such as plasma, etc., and the substrate processing material is sprayed onto the wafer WF through the through holes. In embodiments, the number and shape of the distribution plates of the shower head 450 are not necessarily limited to those illustrated in FIG. 4. The shower head 450 includes a metal, such as aluminum (Al), which easily shaped.

The first and second power supply units 462 and 464 supply power for plasma generation. For example, each of the first and second power supply units 462 and 464 applies a radio frequency (RF) power or a ground in a form of electromagnetic waves that have a predetermined frequency and intensity to the substrate support unit 440 or to the distribution plates of the shower head 450.

The optical emission spectroscopy (OES) 470 is disposed on one side of the chamber 410.

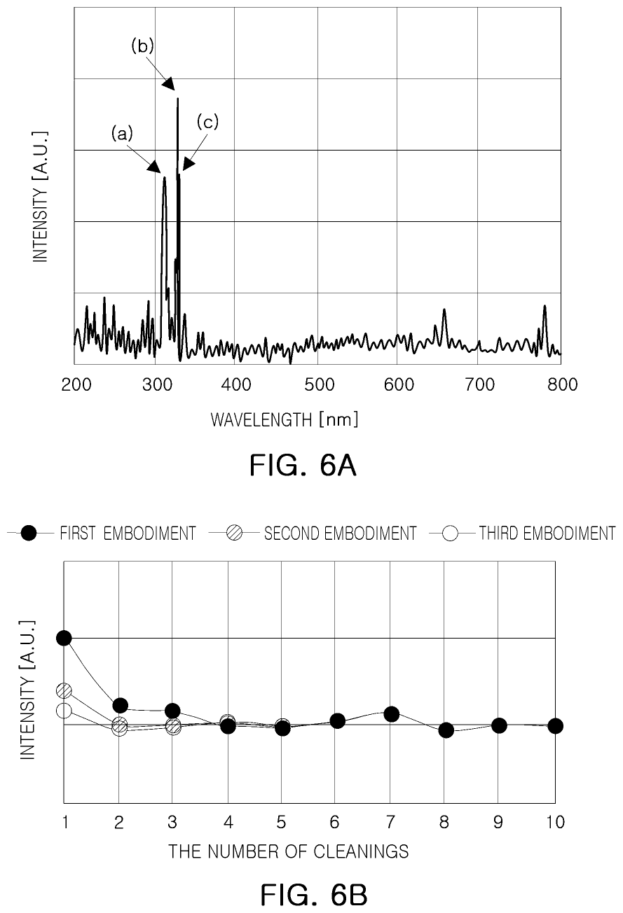

The optical emission spectrometer 470 outputs a signal by detecting the intensity of light generated inside the chamber 410. The optical emission spectrometer 470 outputs an optical signal that is a basis of the analysis in operation S122 of analyzing the intensity of the optical signal at a wavelength that corresponds to copper in the chamber 410, described above with reference to FIG. 1B. From the optical spectrum detected by the optical emission spectrometer 470, a signal according to a degree of copper contamination in the chamber 110 is analyzed. This will be described in more detail below with reference to FIGS. 6A to 8.

FIGS. 5A to 5D illustrate a chamber cleaning method according to embodiments. FIGS. 5A to 5D illustrate an operation S20 of removing copper in the chamber described above with reference to FIG. 1A, and a region that corresponds to the chamber 410 of the substrate processing apparatus 400 of FIG. 4 is illustrated.

Referring to FIGS. 5A and 5B, in an embodiment, a process that forms the copper oxide S110 of FIG. 1A is performed. Hereinafter, when cleaning the chamber 410, a wafer WF that protects an electrostatic chuck of the substrate support portion 440 is loaded in the chamber 410. However, according to embodiments, cleaning can be performed without the wafer WF.

As illustrated in FIG. 5A, in an embodiment, an oxygen (O₂) gas is supplied into the chamber 410 and plasma is generated. Oxygen ions (O²⁻) are generated in the chamber 110, and copper oxide is formed by the following Reaction Formulas (1) and (2).

Cu²⁺+O²⁻→CuO Reaction Formula (1):

2Cu⁺+O²⁻→Cu₂O Reaction Formula (2):

As illustrated in FIG. 5B, in an embodiment, the formed copper oxide is deposited on an inner wall of the chamber 410. Since copper oxide is more stable than copper ions, a phenomenon in which copper drops in a form of particles and contaminates the chamber 110 is reduced. Since operation S110 of forming copper oxide is performed in-situ in the chamber 410, the operation is easily performed between copper-to-copper bonding processes of the wafers WF.

However, when copper oxide remains in the chamber 410 without being removed, is the cooper oxide drops when cracks are generated and contaminates the chamber 410, so the copper oxide needs to be removed at a certain point in time. Accordingly, as described above with reference to FIG. 1A, at a specific point in time, the operation S20 of removing copper includes an operation S110 of forming copper oxide and a first monitoring operation S120 without the operation S130 of removing copper.

Referring to FIGS. 5C and 5D, in an embodiment, the operation S130 of FIG. 1A of removing the copper oxide is performed.

As illustrated in FIG. 5C, at least one of a halogen gas such as chlorine (Cl₂), a nitrogen (N₂) gas, and a hydrogen (H₂) gas is supplied into the chamber 410 to generate plasma. Accordingly, as illustrated in FIG. 5D, the copper oxide in the chamber 110 decomposes and is removed.

For example, when only hydrogen (H₂) is used, copper oxide decomposes according to the following Reaction Formulas (3) and (4), and the decomposed copper is discharged in a vacuum, such that copper is removed.

CuO+H₂→Cu(s)+H₂O Reaction Formula (3):

Cu₂O+H₂→2Cu(s)+H₂O Reaction Formula (4):

For example, when chlorine (Cl₂) and hydrogen (H₂) are used, copper oxide decomposes and is removed by the following Reaction Formulas (5) and (6).

CuO+Cl₂/H₂→CuCl₂(g)+H₂O Reaction Formula (5):

Cu₂O+Cl₂/H₂→2CuCl₂(g)+2H₂O Reaction Formula (6):

For example, when chlorine (Cl₂) is first supplied t and then hydrogen (H₂) is supplied, copper oxide decomposes and is removed by the following Reaction Formulas (7) and (8).

2CuO+2Cl₂→2CuCl₂+O₂ Reaction Formula (7):

3CuCl₂+3H→Cu3Cl₃(g)+HCl(g) Reaction Formula (8):

CuCl₂ is a non-volatile material and is easily removed using hydrogen.

Since operation S130 of removing copper oxide, similar to the operation S110 of forming copper oxide, is performed in-situ in the chamber 410, the operation is easily performed between when the copper-to-copper bonding process of the wafers WF is performed. The operation S130 of removing copper oxide is performed less frequently and with a longer cycle than the operation S110 of forming copper oxide.

FIGS. 6A and 6B are graphs of spectroscopic intensity as functions of wavelength and number of cleanings, respectively, according to embodiments. FIGS. 6A and 6B, illustrate embodiments in which an optical spectrum analysis result when copper is removed from the chamber (operation S20 in FIG. 1A) using oxygen (O₂) plasma, as described above with reference to FIGS. 5A and 5B.

Referring to FIG. 6A, in an embodiment, an optical spectrum measured using the optical emission spectrometer (OES) 170 of FIG. 5B is illustrated, and a method for selecting and analyzing a signal for copper therefrom will be described. In a result of the optical spectrum, a peak (a) is a wavelength band of OH groups that are frequently formed during a plasma process, and a peak (b) is a peak that corresponds to copper, but is excluded from analysis because it overlaps with a wavelength band of CO generated during the process. Since a peak (c) is a peak at a wavelength of about 325 nm that corresponds to copper and does not overlap with the peak of a by-product generated during the process, the peak (c) is selected for intensity analysis. As described above, the intensity can be analyzed by selecting a wavelength or a wavelength band that can represent copper contamination.

According to an embodiment, FIG. 6B illustrates the intensity of peak (c) selected in FIG. 6A according to the number of cleanings of the chamber with respect to first to third embodiments of the chamber cleaning method. Here, the number of cleanings refers to the number of cycles or the number of times of the copper oxide forming process S110 is performed. As the number of chamber cleanings increases, the intensity of the copper peak tends to decrease. In an initial stage of cleaning, the copper signal intensity is decreased by cleaning, and after a certain number of cleanings, reaction of copper ions is completed, so that the intensity no longer changes.

As described above, when embodiments in which the chamber is cleaned using oxygen (O₂) and/or hydrogen (H₂) plasma, the degree of contamination of copper in the chamber can be monitored by the intensity of the optical signal at a specific wavelength representative of copper by an above-described method.

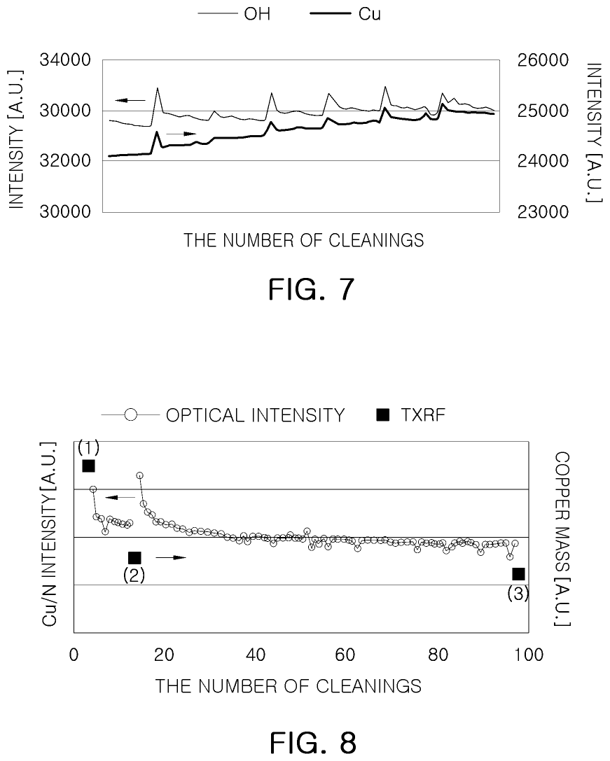

FIG. 7 is a graph of spectroscopic intensity as a function of number of cleanings according to embodiments. FIG. 7 illustrates an optical spectrum analysis result when copper in the chamber is removed using hydrogen (H₂) plasma (operation S20 in FIG. 1A), as described above with reference to FIGS. 5C and 5D.

According to an embodiment, FIG. 7 illustrates the intensity of an optical signal of OH of copper and H₂O generated by the above reaction Formula (3) according to the number of cleanings. As the number of cleaning increases, the graph shows that copper oxide is decomposing and that the intensity of copper and the intensity of OH increase together. The decomposed copper is discharged through evacuation, as described above.

FIG. 8 is a graph of copper contamination as a function of the number of cleanings according to embodiments. FIG. 8 illustrates an optical spectrum analysis result when copper in the chamber is removed using nitrogen (N₂) plasma (operation S20 in FIG. 1A), as described above with reference to FIGS. 5C and 5D.

According to an embodiment, FIG. 8 illustrates a copper peak intensity selected as described above with reference to FIGS. 6A and 6B, and a value obtained by dividing the same by a nitrogen peak intensity according to the number of cleanings of the chamber. When copper in the chamber is removed using nitrogen (N₂) plasma, a copper signal at a wavelength of about 325 nm and a nitrogen signal at a wavelength of about 367 nm overlap. Accordingly, since analyzing only a copper signal is challenging, a degree of copper contamination can be analyzed by a ratio of the intensity of the copper peak to the nitrogen peak, not the intensity of the copper peak.

As illustrated in FIG. 8, as the number of chamber cleanings increases, an intensity ratio of the copper peak/nitrogen peak tends to decrease. Compared with a TXRF quantitative analysis result, in the case of (1), a value of 0.89 is illustrated, and in the case of (2) and (3), a value of 0 is illustrated. Since the optical intensity ratio results and the quantitative analysis results are correlated, the degree of copper contamination can be analyzed by analyzing the optical intensity ratio.

As described above, in the embodiments in which the chamber is cleaned using plasma of a material that overlaps a copper peak, a degree of copper contamination in the chamber is monitored by analyzing the optical signal for copper by an above-described method.

FIG. 9 is a graph of spectroscopic intensity as functions of measurement example according to embodiments.

According to an embodiment, FIG. 9 illustrates optical intensity and copper mass for a plurality of measurement examples. The optical intensity refers to the intensity of a copper signal in a chamber measured using the optical emission spectrometer (OES) 170 of FIG. 4, and the copper mass refers to an amount of copper quantitatively analyzed using TXRF. As illustrated in FIG. 9, the copper signal intensity analyzed by OES and the quantitatively analyzed copper mass illustrate a partial correlation, and the copper mass by TXRF appears to be 0 below a specific intensity value. Based on these results, a reference value for managing a copper contamination degree, such as an optical intensity value of copper having an analysis value of 0 by TXRF can be set. The reference value corresponds to at least one of the first reference value and the second reference value of FIG. 1A. In embodiments, the consistency of the optical intensity and the amount of copper using TEM, etc., can be confirmed.

As set forth above, by including a monitoring operation that can be checked in real time and a contaminant removal operation that uses the monitoring operation, a chamber cleaning method is provided that is easy to perform and can efficiently manage pollution.

While embodiments have been shown and described above, it will be apparent to those skilled in the art that modifications and variations could be made without departing from the scope of embodiments of the present disclosure, as defined by the appended claims.

What is claimed is:

1. A chamber cleaning method, comprising:
processing a wafer using plasma in a chamber; and
removing copper from the chamber,
wherein removing copper includes:
forming copper oxide on an inner wall of the chamber by oxidizing copper in the chamber by a plasma treatment that uses a first gas;
performing a first monitoring operation that monitors a copper contamination state in the chamber using an optical diagnostic method;
removing the copper oxide by a plasma treatment that uses a second gas; and
performing a second monitoring operation that monitors the copper contamination state in the chamber using the optical diagnostic method.

2. The chamber cleaning method of claim 1, wherein each of the first and second monitoring operations comprises:
analyzing a wavelength intensity representative of copper in the chamber with the optical diagnostic method; and
deriving a correlation between a wavelength intensity value and a copper mass analyzed by a quantitative analysis method.

3. The chamber cleaning method of claim 2, wherein the quantitative analysis method comprises a total reflection X-ray fluorescence (TXRF) analysis method.

4. The chamber cleaning method of claim 1, wherein the optical diagnostic method comprises using optical emission spectroscopy (OES).

5. The chamber cleaning method of claim 1, wherein the first monitoring operation is performed in real time while forming the copper oxide on the inner wall of the chamber and the second monitoring operation is performed while removing the copper oxide.

6. The chamber cleaning method of claim 1, wherein the first gas comprises oxygen (O₂).

7. The chamber cleaning method of claim 1, wherein the second gas comprises at least one of chlorine (Cl₂), hydrogen (H₂), or nitrogen (N₂).

8. The chamber cleaning method of claim 1, wherein the plasma treatment uses a capacitively coupled plasma (CCP) method.

9. The chamber cleaning method of claim 1, wherein the wafer is processed in a state in which copper pads for a copper-to-copper bonding are exposed to an upper surface thereof.

10. The chamber cleaning method of claim 1, wherein the wafer is processed by a plasma-treatment that uses at least one of oxygen (O₂) and nitrogen (N₂).

11. A chamber cleaning method, comprising:
processing a wafer using plasma in a chamber;
forming copper oxide on an inner wall of the chamber by oxidizing copper in the chamber by a plasma treatment that uses a first gas;
removing the copper oxide by a plasma treatment that uses a second gas; and
monitoring a copper contamination state in the chamber using optical emission spectroscopy (OES).

12. The chamber cleaning method of claim 11, wherein monitoring a contamination state of copper comprises:
analyzing intensity at a wavelength that represents copper in the chamber, using the OES; and
deriving a correlation between a wavelength intensity value and a copper mass analyzed by a quantitative analysis method.

13. The chamber cleaning method of claim 11, wherein monitoring the copper contamination state is performed after the copper oxide is formed,
wherein, while monitoring the copper contamination state, when a copper contamination degree in the chamber is greater than a reference value, the copper oxide is removed.

14. The chamber cleaning method of claim 11, wherein monitoring the copper contamination state is performed after removing the copper oxide,
wherein, while monitoring the copper contamination state, when a copper contamination degree in the chamber is greater than a reference value, the copper oxide is removed again.

15. The chamber cleaning method of claim 11, wherein monitoring the copper contamination state is performed in real time while forming the copper oxide and removing the copper oxide.

16. The chamber cleaning method of claim 11, wherein processing the wafer is performed before forming the copper oxide and after removing the copper oxide, respectively.

17. A chamber cleaning method, comprising:
monitoring a copper contamination state in a chamber; and
removing copper from the chamber,
wherein monitoring the copper contamination state includes:
analyzing wavelength intensity representative of copper in the chamber with an optical diagnostic method; and
deriving a correlation between a wavelength intensity value and a copper mass analyzed by a quantitative analysis method.

18. The chamber cleaning method of claim 17, wherein, while monitoring the copper contamination state, the intensity value at the wavelength is analyzed in real time.

19. The chamber cleaning method of claim 17, wherein, removing copper from the chamber includes using at least one of a physical method or a chemical method.

20. The chamber cleaning method of claim 19, wherein removing copper from the chamber comprises oxidizing copper in the chamber.
